(19) United States
(12) Patent Application Publication
(10) Pub. No.: US 2026/0305011 A1
(43) Pub. Date: Oct. 1, 2026

(54) HETEROJUNCTION CELL AND MANUFACTURING METHOD THEREOF, PHOTOVOTAIC MODULE, AND PHOTOVOTAIC SYSTEM

(71) Applicant: Trina Solar Co., Ltd., Changzhou (CN)

(72) Inventors: Tingting HUO, Changzhou (CN); Guangtao YANG, Changzhou (CN); Daming CHEN, Changzhou (CN); Hongwei LI, Changzhou (CN); Yanhui BAI, Changzhou (CN); Zibo MENG, Changzhou (CN); Chengli HOU, Changzhou (CN); Zhihao YIN, Changzhou (CN)

(73) Assignee: Trina Solar Co., Ltd., Changzhou (CN)

(21) Appl. No.: 18/996,357

(22) PCT Filed: Dec. 23, 2024
(86) PCT No.: PCT/CN2024/141525

§ 371 Date: Jan. 17, 2025

(30) Foreign Application Priority Data
Oct. 23, 2023 (CN) 202311380099.8

(51) Int. Cl. H10F 77/30; H10F 10/16; H10F 71/00

(52) U.S. Cl. CPC H10F 77/315; H10F 10/16; H10F 71/121

(57) ABSTRACT

The present disclosure relates to a heterojunction cell and a manufacturing method thereof, a photovoltaic module, and a photovoltaic system. The heterojunction cell includes a substrate, and a first intrinsic amorphous silicon layer, a first silicon material layer, and a first transparent conductive oxide layer stacked in sequence on a first side surface of the substrate. The heterojunction cell further includes: a transparent conductive oxide pattern and an anti-reflection layer that are disposed on different regions of a surface of the first transparent conductive oxide layer facing away from the substrate; and a first metal electrode stacked on a surface of the transparent conductive oxide pattern facing away from the substrate.

### CROSS-REFERENCE TO RELATED APPLICATIONS

This application claims priority to Chinese patent application No. 2023113800998, filed on Oct. 23, 2023, the content of which is incorporated herein by reference in its entirety.

### TECHNICAL FIELD

The present disclosure relates to the field of solar cell technologies, and more particularly, to a heterojunction cell and a manufacturing method thereof, a photovoltaic module, and a photovoltaic system.

### BACKGROUND

In recent years, with the rapid development of the photovoltaic industry, domestic and foreign markets have put forward increasingly higher requirements for the conversion efficiency and product performance of solar cells and photovoltaic modules. This has also prompted industry manufacturers to actively research and develop new cells, module structures and related processes. Heterojunction (HJT) cells have the advantages of low light attenuation, low temperature coefficient, etc., they can reduce energy consumption while reducing thermal damage to silicon substrates, and thus have become an important direction for the development of high-efficiency cells in the future. The HJT cell is formed mainly by depositing intrinsic amorphous silicon films and then depositing P-type amorphous or microcrystalline silicon films and N-type amorphous or microcrystalline silicon films respectively, on both sides of the silicon substrate to form HJTs, and then forming respective transparent conductive oxide (TCO) layers on surfaces of the amorphous or microcrystalline silicon films on the both sides of the silicon substrate, then performing screen printing with a low-temperature silver paste and solidifying it to form surface metal electrodes. The TCO layers play a vital role in the structure of the heterojunction cell, and can provide dual functions of excellent optical and electrical performances. However, the TCO material intrinsically has a certain parasitic absorption, which may cause loss of the light absorption of the heterojunction cell and affects the efficiency of the heterojunction cell.

### SUMMARY

According to various embodiments of the present disclosure, a highly efficient heterojunction cell and a manufacturing method thereof, a photovoltaic module, and a photovoltaic system are provided.

A first aspect of embodiments of the present disclosure provides a heterojunction cell, which includes a substrate, and a first intrinsic amorphous silicon layer, a first silicon material layer, and a first transparent conductive oxide layer disposed in sequence on a first side surface of the substrate.

The heterojunction cell further includes a transparent conductive oxide pattern, an anti-reflection layer, and a first metal electrode. The transparent conductive oxide pattern and the anti-reflection layer are disposed on different regions of a surface of the first transparent conductive oxide layer facing away from the substrate. The first metal electrode is stacked on a surface of the transparent conductive oxide pattern facing away from the substrate.

In one of the embodiments, the region in which the transparent conductive oxide pattern is disposed, is complementary to the region in which the anti-reflection layer is disposed.

In one of the embodiments, a projection of the transparent conductive oxide pattern on the first transparent conductive oxide layer covers a projection of the first metal electrode on the first transparent conductive oxide layer.

In one of the embodiments, the first metal electrode includes at least two busbars that are parallel to each other and are spaced apart from each other. Each of the busbars is electrically connected to at least two fingers.

At least two transparent conductive oxide patterns are provided. The transparent conductive oxide patterns are spaced apart from each other. The transparent conductive oxide patterns are disposed in a one-to-one correspondence with the busbars.

In one of the embodiments, the anti-reflection layer is configured as a single layer structure, and the anti-reflection layer includes one of a SiNx layer, a SiOx layer, a SiNxOy layer, and a AlOx layer; or
the anti-reflection layer is configured as a composite layer, and the composite layer includes at least two of a SiNx layer, a SiOx layer, a SiNxOy layer, and a AlOx layer.

In one of the embodiments, a thickness of the first transparent conductive oxide layer is in a range of 20 nm to 60 nm, and a thickness of the transparent conductive oxide pattern is in a range of 40 nm to 100 nm.

A second aspect of embodiments of the present disclosure provides a manufacturing method of a heterojunction cell, and the manufacturing method includes:
providing a base plate, the base plate includes a substrate, and a first intrinsic amorphous silicon layer, a first silicon material layer, and a first transparent conductive oxide layer that are stacked in sequence on a first side surface of the substrate, and a second intrinsic amorphous silicon layer, a second silicon material layer, and a second transparent conductive oxide layer that are stacked in sequence on a second side surface of the substrate; a doping type of the first silicon material layer being opposite to a doping type of the second silicon material layer, and the first side surface being opposed to the second side surface;
forming a transparent conductive oxide pattern and an anti-reflection layer on different regions of a surface of the first transparent conductive oxide layer facing away from the substrate; and
forming a first metal electrodes on a surface of the transparent conductive oxide pattern facing away from the substrate.

In one of the embodiments, forming the transparent conductive oxide pattern and the anti-reflection layer on the different regions of the surface of the first transparent conductive oxide layer facing away from the substrate includes:
forming the transparent conductive oxide pattern on the surface of the first transparent conductive oxide layer facing away from the substrate by means of a mask; and
forming the anti-reflection layer on a region of the surface of the first transparent conductive oxide layer facing away from the substrate, that is not covered by the transparent conductive oxide pattern.

In one of the embodiments, providing the base plate includes:
forming the first intrinsic amorphous silicon layer and the second intrinsic amorphous silicon layer on the first side surface and the second side surface of the substrate respectively; the first side surface and the second side surface being opposed to each other;
forming the first silicon material layer on a surface of the first intrinsic amorphous silicon layer facing away from the substrate, and forming the second silicon material layer on a surface of the second intrinsic amorphous silicon layer facing away from the substrate; and
forming the second transparent conductive oxide layer on a surface of the second silicon material layer facing away from the substrate, and forming the first transparent conductive oxide layer on a surface of the first silicon material layer facing away from the substrate.

In one of the embodiments, the manufacturing method further includes, after forming the first metal electrode on the surface of the transparent conductive oxide pattern facing away from the substrate:
forming a second metal electrode on a surface of the second transparent conductive oxide layer facing away from the substrate.

A third aspect of an embodiment of the present disclosure provides a photovoltaic module. The photovoltaic module includes at least one cell string. The cell string includes at least two above heterojunction cells.

A fourth aspect of an embodiment of the present disclosure provides a photovoltaic system. The photovoltaic system includes the above photovoltaic module.

The above heterojunction cell and the manufacturing method thereof, the photovoltaic module, and the photovoltaic system have advantageous effects as follows.

### BRIEF DESCRIPTION OF THE DRAWINGS

FIG. 1 is a schematic diagram of a structure of a heterojunction cell according to an embodiment of the present disclosure.

FIG. 2 is a flow chart of a manufacturing method of a heterojunction cell according to an embodiment of the present disclosure.

FIG. 3 is a schematic diagram of a structure of a base plate in the manufacturing method of the heterojunction cell according to an embodiment of the present disclosure.

FIG. 4 is a schematic diagram of a structure with transparent conductive oxide patterns and an anti-reflection layer formed on a first transparent conductive oxide layer in the manufacturing method of the heterojunction cell according to an embodiment of the present disclosure.

FIG. 5 is a schematic diagram of a structure with first metal electrodes and second metal electrodes manufactured in the manufacturing method of the heterojunction cell according to an embodiment of the present disclosure.

ILLUSTRATION FOR REFERENCE NUMERALS
100. heterojunction cell; 101. base plate;
10. substrate; 20. first intrinsic amorphous silicon layer; 30. first silicon material layer; 40. first transparent conductive oxide layer; 50. transparent conductive oxide pattern; 60. anti-reflection layer; 70. second intrinsic amorphous silicon layer; 80. second silicon material layer; 90. second transparent conductive oxide layer; 91. first metal electrode; 92. second metal electrode;

C1. first side surface; C2. second side surface.

### DETAILED DESCRIPTION OF THE EMBODIMENTS

In order to make the above purposes, features and advantages of the present disclosure more apparent and better understood, embodiments of the present disclosure will be fully described hereinafter with reference to the accompanying drawings. In the following description, many specific details are set forth in order to fully understand the present disclosure. However, the present disclosure can be implemented in many other ways than those described herein, and similar modifications may be made by those skilled in the art without departing from the scope of the disclosure, which is therefore not to be limited to the specific embodiments disclosed below.

In the description of the present disclosure, it should be understood that the orientation or positional relationship indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential”, or the like, is based on the orientation or positional relationship shown in the drawings, only to facilitate the description of the present disclosure and simplify the description, rather than indicating or implying the device or elements must have a specific orientation, be constructed and operated in a specific orientation, and therefore cannot be construed as limitation of the present disclosure.

In addition, the terms “first” and “second” are used for purposes of description only, and cannot be understood to indicate or imply relative importance or implicitly indicate the number of technical features indicated. Therefore, the features defined by “first” and “second” may explicitly or implicitly include at least one of the features. In the description of the present disclosure, the meaning of “plurality” is at least two, such as two, three, or more, unless otherwise clearly and specifically defined.

In the present disclosure, unless otherwise clearly specified and defined, the term such as “installation”, “coupling”, “connection”, “fixation” should be understood in a broad sense, for example, it can be a fixed connection or a detachable connection, or integrated; or may be a mechanical connection or an electrical connection; may be a direct connection, or may be an indirect connection through an intermediate medium; or may be a communication between two components or an interaction between two components, unless otherwise specified. Those ordinary skilled in the art can understand the specific meanings of the above terms in the present disclosure according to specific circumstance.

In the present disclosure, unless otherwise clearly specified and defined, a first feature being “on” or “below” a second feature may refer to that the first and second features are in direct contact, or the first and second features are indirectly contact through an intermediate medium. The first feature being “at the top of”, “above”, and “over” the second feature may indicate that the first feature is directly or obliquely above the second feature, or only indicate that the first feature is higher in level than that of the second feature. The expression that a first feature is “beneath”, “below”, and “under” the second feature may indicate that the first feature is directly or obliquely below the second feature, or only indicates that the first feature is lower in level than that of the second feature.

It should be noted that an element, when being referred to as being “fixed”, or “disposed” on another element, it may be directly on the another element, or there may be an intermediate element between them. When an element is considered to be “connected” to another element, it may be directly connected to the another element or there may be an intermediate element between them at the same time. The terms “vertical”, “horizontal”, “upper”, “lower”, “left”, “right” and similar expressions used herein are for illustrative purposes only and should not be construed as the unique implementation.

A heterojunction cell and a manufacturing method thereof, a photovoltaic module, and a photovoltaic system of embodiments of the present disclosure will be described below with reference to the accompanying drawings. The heterojunction cell of the present disclosure can address the problem of large loss of light absorption and low efficiency of the heterojunction cell in the related art.

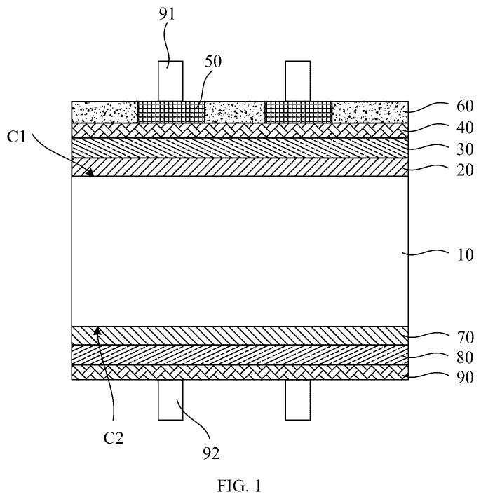

FIG. 1 is a schematic diagram of a structure of a heterojunction cell 100 according to an embodiment of the present disclosure.

Referring to FIG. 1, a first aspect of embodiments of the present disclosure provides a heterojunction cell 100. The heterojunction cell 100 includes a substrate 10, and a first intrinsic amorphous silicon layer 20, a first silicon material layer 30, and a first transparent conductive oxide layer 40 disposed in sequence on a first side surface C1 of the substrate 10.

The heterojunction cell 100 further includes transparent conductive oxide patterns 50, an anti-reflection layer 60, and first metal electrodes 91. The transparent conductive oxide patterns 50 and the anti-reflection layer 60 are disposed on different regions of a surface of the first transparent conductive oxide layer 40 facing away from the substrate 10. The first metal electrodes 91 are stacked on surfaces of the transparent conductive oxide patterns 50 facing away from the substrate 10 respectively.

For example, the first side may be a light receiving side of the heterojunction cell 100. The second side is disposed opposite to the first side, and for example, the second side may be a backlighting side. The transparent conductive oxide patterns 50 and the anti-reflection layer 60 being disposed on different regions of the surface of the first transparent conductive oxide layer 40 facing away from the substrate 10 means that, when viewing downwardly from above, the transparent conductive oxide patterns 50 and the anti-reflection layer 60 do not overlap with each other, and are located in different regions, while the transparent conductive oxide patterns 50 and the anti-reflection layer 60 can be located in a same layer.

By disposing the transparent conductive oxide patterns 50 and the anti-reflection layer 60 on different regions of the surface of the first transparent conductive oxide layer 40 facing away from the substrate 10, the transparent conductive oxide patterns 50 and the first transparent conductive oxide layer 40 form a transparent conductive oxide layer on a light receiving side of the heterojunction cell 100. In this way, a part of the region on the light receiving side of the heterojunction cell 100 is disposed as the anti-reflection layer 60. Compared with the configuration in which a transparent conductive oxide layer is disposed on the entire surface on the light receiving side of the heterojunction cell 100, with the same thickness of the transparent conductive oxide layer, in the present application, since the region for disposing the transparent conductive oxide layer on the light receiving side of the heterojunction cell is reduced, the parasitic absorption of the transparent conductive oxide layer can be reduced. In addition, the anti-reflection layer 60 can further reduce the reflectivity to the light to be absorbed, so that the short-circuit current can be improved, and the optical performance of the heterojunction cell 100 can be optimized. In addition, by disposing the first transparent conductive oxide layer 40 below the transparent conductive oxide patterns 50, the carrier transmission performance is improved while the contact resistance is reduced, and it can be ensured that the electrical performance of the heterojunction cell 100 does not decrease.

In other words, the metal contact regions below the first metal electrodes 91 are the transparent conductive oxide patterns 50, and the non-busbar regions (non-metal-electrode regions) are the anti-reflection layer 60. Compared with a design in which the transparent conductive oxide layer is disposed on the whole surface, the design of the patterned transparent conductive oxide patterns 50 of the present disclosure is beneficial to the reduction of the parasitic absorption, and the anti-reflection layer 60 can have an excellent anti-reflection effect, which further improves the spectral absorption capability of the cell. In a direction towards the substrate 10, Under, the first transparent conductive oxide layer 40 is disposed below the film layers such as the patterned transparent conductive oxide patterns 50 and the anti-reflection layer 60, which is beneficial to the longitudinal transmission and collection of carriers in the doped layers, thereby improving the electrical performance of the heterojunction cell 100.

In the embodiment of the present disclosure, the first transparent conductive oxide layer 40 may be disposed on the whole layer on the first side (the light receiving side) of the heterojunction cell 100, so that the transmission performance of the carriers can be further improved. The regions in which the anti-reflection layer 60 is disposed, are non-metal-electrode regions.

Further, the thickness of the first transparent conductive oxide layer 40 is in a range of 20 nm to 60 nm, for example, may be 20 nm, 25 nm, 30 nm, 35 nm, 40 nm, 45 nm, 50 nm, 55 nm, or 60 nm. The thickness of the transparent conductive oxide pattern 50 is in a range of 40 nm to 100 nm, for example, may be 40 nm, 45 nm, 50 nm, 55 nm, 60 nm, 65 nm, 70 nm, 75 nm, 80 nm, 85 nm, 90 nm, 95 nm, or 100 nm. Further, the thickness of the anti-reflection layer 60 may be, for example, in a range of 60 nm to 140 nm, for example, may be 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm or 140 nm.

In an embodiment of the present disclosure, the regions in which the transparent conductive oxide patterns 50 are disposed, are complementary to the regions in which the anti-reflection layer 60 is disposed. This means that the outer contour of the transparent conductive oxide patterns 50 and the outer contour of the anti-reflection layer 60 correspond to each other, match each other, and are complementary to each other. For example, both the transparent conductive oxide patterns 50 and the anti-reflection layer 60 are disposed on the first transparent conductive oxide layer 40, and the regions of the surface of the first transparent conductive oxide layer 40 which are not covered by the transparent conductive oxide patterns 50, are fully covered by the anti-reflection layer 60.

Further, the first metal electrodes 91 include at least two busbars (not shown) that are parallel to each other and are spaced apart from each other. Each of the busbars is electrically connected to at least two fingers (not shown). At least two transparent conductive oxide patterns 50 are provided. The transparent conductive oxide patterns 50 are disposed spaced apart from each other. The transparent conductive oxide patterns 50 are disposed in a one-to-one correspondence with the busbars. In other words, one transparent conductive oxide pattern 50 corresponds to one busbar and fingers connected to the busbar. In this way, on the light receiving side of the heterojunction cell 100, the patterned transparent conductive oxide patterns 50 and the anti-reflection layer 60 are arranged alternately.

In an embodiment of the present disclosure, a projection of the transparent conductive oxide pattern 50 on the first transparent conductive oxide layer 40 covers a projection of the respective first metal electrode 91 on the first transparent conductive oxide layer 40. Herein, this may mean that, the projection of the respective first metal electrode 91 on the first transparent conductive oxide layer 40 completely overlaps with the projection of the transparent conductive oxide pattern 50 on the first transparent conductive oxide layer 40. That is, when viewing downwardly from the top, the outer contour of the transparent conductive oxide patterns 50 and the outer contour of the first metal electrodes 91 are the same. Alternatively, this may mean that, the edge of the projection of the transparent conductive oxide patterns 50 on the first transparent conductive oxide layer 40 is located outside the edge of the projection of the respective first metal electrodes 91 on the first transparent conductive oxide layer 40. That is, when viewing downwardly from the top, the coverage of the outer contour of the transparent conductive oxide patterns 50 is greater than the coverage of the outer contour of the first metal electrodes 91.

In an embodiment of the present disclosure, still referring to FIG. 1, the heterojunction cell 100 further includes a second intrinsic amorphous silicon layer 70, a second silicon material layer 80, and a second transparent conductive oxide layer 90 that are stacked in sequence on a second side surface C2 of the substrate 10. A doping type of the first silicon material layer 30 is opposite to a doping type of the second silicon material layer 80. The first side surface C1 and the second side surface C2 are opposed to each other. Exemplarily, the substrate 10 may be of N-type or P-type. When the substrate 10 is of N-type, the first silicon material layer 30 may be an N-type material layer, and the second silicon material layer 80 may be a P-type material layer.

Herein, the first silicon material layer 30 may be, for example, N-type doped amorphous silicon or N-type doped microcrystalline silicon, and the second silicon material layer 80 may be, for example, P-type doped amorphous silicon or P-type doped microcrystalline silicon.

The first transparent conductive oxide layer 40, the second transparent conductive oxide layer 90, and the transparent conductive oxide patterns 50 may be made of, for example, indium tin oxide (ITO), tungsten doped indium oxide (IWO), cerium-doped indium oxide (ICO), and aluminum-doped zinc oxide (AZO).

Further, the anti-reflection layer 60 is configured as a single layer structure, and the anti-reflection layer 60 includes one of a SiNx layer, a SiOx layer, a SiNxOy layer, and a AlOx layer.

Alternatively, the anti-reflection layer 60 is configured as a composite layer, and the composite layer includes at least two of a SiNx layer, a SiOx layer, a SiNxOy layer, and a AlOx layer.

In an embodiment of the present disclosure, the thicknesses of the first intrinsic amorphous silicon layer 20 and the second intrinsic amorphous silicon layer 70 may each be, for example, in a range of 4 nm to 25 nm; and the thicknesses of the first silicon material layer 30 and the second silicon material layer 80 may each be, for example, in a range of 8 nm to 35 nm.

The thickness of the second transparent conductive oxide layer 90 is in a range of 60 nm to 150 nm.

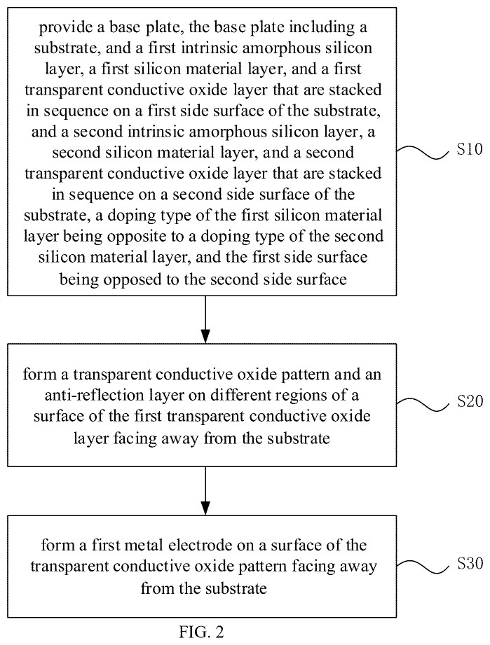

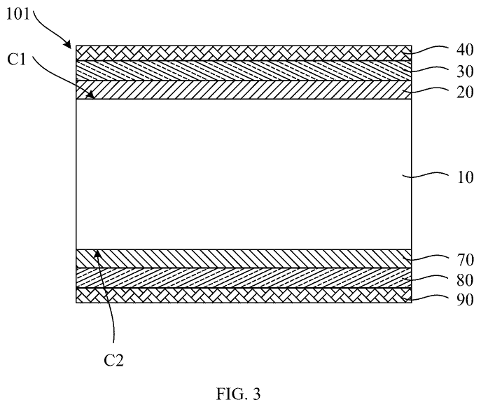

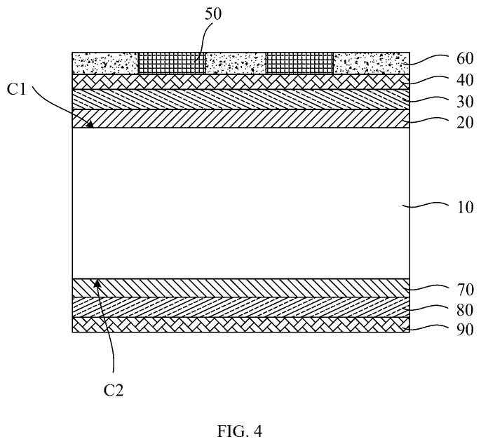

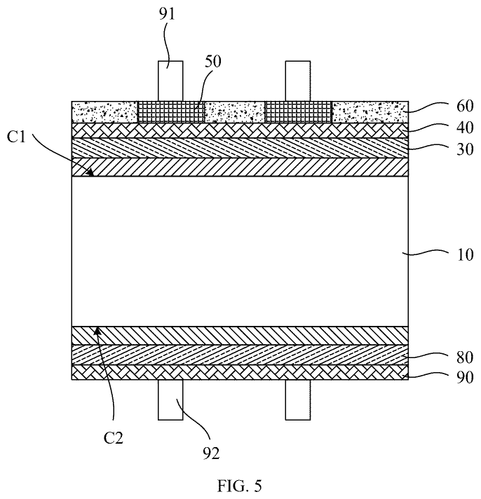

FIG. 2 is a flow chart of a manufacturing method of a heterojunction cell according to an embodiment of the present disclosure; FIG. 3 is a schematic diagram of a structure of a base plate in the manufacturing method of the heterojunction cell according to an embodiment of the present disclosure; FIG. 4 is a schematic diagram of a structure with transparent conductive oxide patterns 50 and an anti-reflection layer 60 formed on a first transparent conductive oxide layer 40 in the manufacturing method of the heterojunction cell according to an embodiment of the present disclosure; and FIG. 5 is a schematic diagram of a structure with first metal electrodes 91 and second metal electrodes 92 manufactured in the manufacturing method of the heterojunction cell according to an embodiment of the present disclosure.

Referring to FIGS. 2 to 5, a second aspect of embodiments of the present disclosure further provides a manufacturing method of a heterojunction cell. The manufacturing method includes the following steps of S10 to S30.

At S10, a base plate is provided. The base plate includes: a substrate 10; a first intrinsic amorphous silicon layer 20, a first silicon material layer 30, and a first transparent conductive oxide layer 40 that are stacked in sequence on a first side surface C1 of the substrate 10; and a second intrinsic amorphous silicon layer 70, a second silicon material layer 80, and a second transparent conductive oxide layer 90 that are stacked in sequence on a second side surface C2 of the substrate 10. A doping type of the first silicon material layer 30 is opposite to a doping type of the second silicon material layer 80. The first side surface C1 and the second side surface C2 are opposed to each other.

At S20, transparent conductive oxide patterns 50 and an anti-reflection layer 60 are formed on different regions of a surface of the first transparent conductive oxide layer 40 facing away from the substrate 10.

At S30, first metal electrodes 91 are formed on surfaces of the transparent conductive oxide patterns 50 facing away from the substrate 10 respectively.

By disposing the transparent conductive oxide patterns 50 and the anti-reflection layer 60 on different regions of the surface of the first transparent conductive oxide layer 40 facing away from the substrate 10, and forming the first metal electrodes 91 on the surfaces of the transparent conductive oxide patterns 50 facing away from the substrate 10 respectively, the transparent conductive oxide patterns 50 and the first transparent conductive oxide layer 40 can form a transparent conductive oxide layer on the light receiving side of the heterojunction cell 100. In other words, by disposing a part of the region on the light receiving side of the heterojunction cell 100 as the anti-reflection layer 50, compared with the configuration in which a transparent conductive oxide layer is disposed on the entire surface on the light receiving side of the heterojunction cell 100, with the same thickness of the transparent conductive oxide layer, in the present application, since the region for disposing the transparent conductive oxide layer on the light receiving side of the heterojunction cell is reduced, the parasitic absorption of the transparent conductive oxide layer can be reduced. In addition, the anti-reflection layer 60 can further reduce the reflectivity to the light to be absorbed, so that the short-circuit current can be improved, and the optical performance of the heterojunction cell 100 can be optimized. In addition, by disposing the first transparent conductive oxide layer 40 below the transparent conductive oxide patterns 50, the carrier transmission performance is improved while the contact resistance is reduced, and it can be ensured that the electrical performance of the heterojunction cell 100 does not decrease.

Further, in step S20, the step of forming the transparent conductive oxide patterns 50 and the anti-reflection layer 60 on different regions of the surface of the first transparent conductive oxide layer 40 facing away from the substrate 10 specifically includes steps of:
forming the transparent conductive oxide patterns 50 on the surface of the first transparent conductive oxide layer 40 facing away from the substrate 10 by means of a mask; and
forming the anti-reflection layer 60 on regions of the surface of the first transparent conductive oxide layer 40 facing away from the substrate 10, that are not covered by the transparent conductive oxide patterns 50.

In this way, the transparent conductive oxide patterns 50 and the anti-reflection layer 60 formed as above may be complementary to each other.

Referring to FIG. 3, in an embodiment of the present disclosure, in step S10, the step of providing the base plate 101 specifically includes steps of:
forming a first intrinsic amorphous silicon layer 20 and a second intrinsic amorphous silicon layer 70 on the first side surface C1 and the second side surface C2 of the substrate 10 respectively; the first side surface C1 being opposed to the second side surface C2; and
forming a first silicon material layer 30 on a surface of the first intrinsic amorphous silicon layer 20 facing away from the substrate 10, and forming a second silicon material layer 80 on a surface of the second intrinsic amorphous silicon layer 70 facing away from the substrate 10; and
forming a second transparent conductive oxide layer 90 on a surface of the second silicon material layer 80 facing away from the substrate 10, and forming a first transparent conductive oxide layer 40 on a surface of the first silicon material layer 30 facing away from the substrate 10.

Further, in step S30, the method further includes, after the step of forming the first metal electrodes 91 on the surfaces of the transparent conductive oxide patterns 50 facing away from the substrate 10 respectively, step of:
forming second metal electrodes on a surface of the second transparent conductive oxide layer 90 facing away from the substrate 10.

A specific example of the manufacturing method of the heterojunction cell according to an embodiment of the present disclosure is given below for illustration. The manufacturing method includes the following steps of step 1 to step 5.

At step 1: referring to FIG. 3, a silicon wafer is used as a substrate 10. Both sides of the silicon wafer are treated by texturing, to obtain a textured surface morphology including a geometric pattern including normal and inverted pyramids. A size of each of the pyramids is in a range of 0.5 μm to 10 μm. The reflectivity of the first side surface C1 of the substrate 10 is in a range of 6% to 16%. In addition, the process of the texturing is a chemical wet process, and the texturing is easily performed by using an alkali solution or an acid.

At Step 2: referring to FIG. 3, intrinsic amorphous silicon is formed as the first intrinsic amorphous silicon layer 20 and the second intrinsic amorphous silicon layer 70 on the first side surface C1 and the second side surface C2 of the substrate 10 respectively. N-type doped amorphous silicon or microcrystalline silicon is formed as the first silicon material layer 30 on the surface of the first intrinsic amorphous silicon layer 20 facing away from the substrate 10, and P-type doped amorphous silicon or microcrystalline silicon is formed as the second silicon material layer 80 on the surface of the second intrinsic amorphous silicon layer 70 facing away from the substrate 10. The device used in step 2 is a plasma enhanced chemical vapor deposition (PECVD) device or a hot wire chemical vapor deposition (HWCVD) device. The thicknesses of the first intrinsic amorphous silicon layer 20 and the second intrinsic amorphous silicon layer 70 may each be, for example, in a range of 4 nm to 25 nm, and the thicknesses of the first silicon material layer 30 and the second silicon material layer 80 may each be, for example, in a range of 8 nm to 35 nm.

At Step 3: referring to FIG. 3, the second transparent conductive oxide layer 90 is formed on the surface of the second silicon material layer 80 facing away from the substrate 10, and during this process, the device used is a physical vapor deposition (PVD) device or a reactive plasma deposition (RPD) device. A thickness of the second transparent conductive oxide layer 90 is in a range of 60 nm to 150 nm. The first transparent conductive oxide layer 40 is formed on the surface of the first silicon material layer 30 facing away from the substrate 10, and during this process, the device used is a physical vapor deposition (PVD) device or a ROD device, and a thickness of the first transparent conductive oxide layer 40 is in a range of 20 nm to 60 nm.

At Step 4: referring to FIG. 4, the transparent conductive oxide patterns 50 and the anti-reflection layer 60 are formed on different regions of the surface of the first transparent conductive oxide layer 40 facing away from the substrate 10 by means of a mask. A thickness of each of the transparent conductive oxide patterns 50 is in a range of 40 nm to 100 nm. The device used for deposition is a PVD device or a RPD device. The anti-reflection layer 60 are deposited by means of a mask. The anti-reflection layer 60 includes, but is not limited to, a single layer of SiNx or a stack of layers of SiNx, a stack of layers of SiNx and SiOx, a stack of layers of SiNxOy and SiNx, or a stack of layers of AlOx and SiNx, or the like. The anti-reflection layer 60 is complementary to the transparent conductive oxide patterns 50. A device used to form the anti-reflection layer 60 is a low-temperature PECVD device, a low-temperature APCVD device, or the like. A total thickness of the anti-reflection layer 60 is in a range of 60 nm to 140 nm.

At Step 5: referring to FIG. 5, the first metal electrodes 91 are formed on surfaces of the transparent conductive oxide patterns 50 facing away from the substrate 10 respectively. The second metal electrodes 92 are formed on the surface of the second transparent conductive oxide layer 90 facing away from the substrate 10.

A third aspect of the present disclosure further provides a photovoltaic module. The photovoltaic module includes at least one cell string. The cell string includes at least two heterojunction cells 100 as described above. The heterojunction cells 100 may be connected together by series welding, so that electric energy generated by the individual heterojunction cells 100 can be collected together for subsequent transmission. In other embodiments, the heterojunction cells 100 may be spaced apart, or may be stacked together in a shingled form.

Exemplarily, the photovoltaic module further includes an encapsulation layer and a cover plate. The encapsulation layer is configured to cover a surface of the cell string. The cover plate is configured to cover a surface of the encapsulation layer away from the cell string.

A fourth aspect of the present disclosure further provides a photovoltaic system. The photovoltaic system includes the above photovoltaic module.

The photovoltaic system may be applied to a photovoltaic power station, such as a ground surface power station, a roof power station, a water surface power station, or the like, or may be applied to a device or an apparatus that generates power by using solar energy, such as a user solar power supply, a solar street lamp, a solar vehicle, a solar building, or the like. It is to be understood that the application scenario of the photovoltaic system is not limited thereto. In other words, the photovoltaic system may be applied to all fields in which solar energy needs to be used for generating power. Taking the photovoltaic power generation system network as an example, the photovoltaic system may include photovoltaic arrays, a combiner box, and an inverter. The photovoltaic array may be an array combination of a plurality of photovoltaic modules. For example, a plurality of photovoltaic modules may form a plurality of photovoltaic arrays. The photovoltaic arrays are connected to a combiner box, and then the combiner box may combine the current generated by the photovoltaic arrays. The combined current flows through an inverter and is converted into an alternating current required by a mains power network, and is then input to the mains power network to implement solar power supply.

In the heterojunction cell and the manufacturing method thereof, the photovoltaic module, and the photovoltaic system of the present disclosure, the heterojunction cell has a relatively small loss of light absorption and relatively high efficiency.

Each of the technical features of the above-mentioned embodiments may be combined arbitrarily. To simplify the description, not all the possible combinations of each of the technical features in the above embodiments are described. However, all of the combinations of these technical features should be considered as within the scope of this disclosure, as long as such combinations do not contradict with each other.

The above-described embodiments merely illustrate several embodiments of the present disclosure, which are described more specifically and in detail, but they cannot be understood as limiting the scope of the present disclosure. It should be noted that, for those ordinary skilled in the art, several variations and improvements may be made without departing from the concept of the present disclosure, and all of which are within the protection scope of the present disclosure. Therefore, the scope of protection of the present disclosure shall be subject to the appended claims.

1. A heterojunction cell, comprising:
a substrate;
a first intrinsic amorphous silicon layer, a first silicon material layer, and a first transparent conductive oxide layer that are disposed in sequence on a first side surface of the substrate;
a transparent conductive oxide pattern and an anti-reflection layer that are disposed on different regions of a surface of the first transparent conductive oxide layer facing away from the substrate; and
a first metal electrode stacked on a surface of the transparent conductive oxide pattern facing away from the substrate.

2. The heterojunction cell according to claim 1, wherein the region in which the transparent conductive oxide pattern is disposed, is complementary to the region in which the anti-reflection layer is disposed.

3. The heterojunction cell according to claim 2, wherein a projection of the transparent conductive oxide pattern on the first transparent conductive oxide layer covers a projection of the first metal electrode on the first transparent conductive oxide layer.

4. The heterojunction cell according to claim 1, wherein the first metal electrode includes at least two busbars that are parallel to each other and are spaced apart from each other, each of the busbars is electrically connected to at least two fingers; and
at least two transparent conductive oxide patterns are provided; the transparent conductive oxide patterns are spaced apart from each other; and the transparent conductive oxide patterns are disposed in a one-to-one correspondence with the busbars.

5. The heterojunction cell according to claim 1, wherein the anti-reflection layer is configured as a single layer structure, and the anti-reflection layer includes one of a SiNx layer, a SiOx layer, a SiNxOy layer, and a AlOx layer; or
the anti-reflection layer is configured as a composite layer, and the composite layer includes at least two of a SiNx layer, a SiOx layer, a SiNxOy layer, and a AlOx layer.

6. The heterojunction cell according to claim 1, wherein a thickness of the first transparent conductive oxide layer is in a range of 20 nm to 60 nm, and a thickness of the transparent conductive oxide pattern is in a range of 40 nm to 100 nm.

7. A manufacturing method of a heterojunction cell, comprising:
providing a base plate, the base plate including a substrate, and a first intrinsic amorphous silicon layer, a first silicon material layer, and a first transparent conductive oxide layer that are stacked in sequence on a first side surface of the substrate, and a second intrinsic amorphous silicon layer, a second silicon material layer, and a second transparent conductive oxide layer that are stacked in sequence on a second side surface of the substrate, a doping type of the first silicon material layer being opposite to a doping type of the second silicon material layer, and the first side surface being opposed to the second side surface;
forming a transparent conductive oxide pattern and an anti-reflection layer on different regions of a surface of the first transparent conductive oxide layer facing away from the substrate; and
forming a first metal electrode on a surface of the transparent conductive oxide pattern facing away from the substrate.

8. The manufacturing method according to claim 7, wherein forming the transparent conductive oxide pattern and the anti-reflection layer on the different regions of the surface of the first transparent conductive oxide layer facing away from the substrate includes:
forming the transparent conductive oxide pattern on the surface of the first transparent conductive oxide layer facing away from the substrate by means of a mask; and
forming the anti-reflection layer on a region of the surface of the first transparent conductive oxide layer facing away from the substrate, that is not covered by the transparent conductive oxide pattern.

9. The manufacturing method according to claim 7, wherein providing the base plate includes:
forming the first intrinsic amorphous silicon layer and the second intrinsic amorphous silicon layer on the first side surface and the second side surface of the substrate respectively;
forming the first silicon material layer on a surface of the first intrinsic amorphous silicon layer facing away from the substrate, and forming the second silicon material layer on a surface of the second intrinsic amorphous silicon layer facing away from the substrate;
forming the second transparent conductive oxide layer on a surface of the second silicon material layer facing away from the substrate, and forming the first transparent conductive oxide layer on a surface of the first silicon material layer facing away from the substrate.

10. The manufacturing method according to claim 7, wherein forming the first metal electrode on the surface of the transparent conductive oxide pattern facing away from the substrate includes:
forming a second metal electrode on a surface of the second transparent conductive oxide layer facing away from the substrate.

11. A photovoltaic module, comprising at least one cell string, the cell string including at least two heterojunction cells of claim 1.

12. A photovoltaic system, comprising the photovoltaic module of claim 11.
